(19) United States
(12) Patent Application Publication
(10) Pub. No.: US 2025/0190642 A1
(43) Pub. Date: Jun. 12, 2025

(54) DISTANCE-BASED ESTIMATION OF ENERGY PROPAGATION VARIATION IN SYNTHETIC THREE-DIMENSIONAL SCENES

(71) Applicant: Microsoft Technology Licensing, LLC, Redmond, WA (US)

(72) Inventors: John Michael SNYDER, Redmond, WA (US); Nikunj RAGHUVANSHI, Redmond, WA (US); Michael G. CHEMISTRUCK, Issaquah, WA (US)

(73) Assignee: Microsoft Technology Licensing, LLC, Redmond, WA (US)

(21) Appl. No.: 18/531,360

(22) Filed: Dec. 6, 2023

(51) Int. Cl. G06F 30/13

(52) U.S. Cl. CPC G06F 30/13

(57) ABSTRACT

This document relates to distance-based estimation of energy propagation variation in synthetic three-dimensional scenes. For example, the disclosed implementations can detect geometric features, such as outside corners or portals, based on a distance field that identifies distances from points in a scene to the nearest geometry in the scene. Then, energy propagation variation within the scene can be estimated based on the locations of the geometric features. Energy propagation variation can be employed for a range of applications, such as deploying sampling probes within a given scene and simulating energy propagation to/from the probes within the scene.

### BACKGROUND

Synthetic three-dimensional scenes can be employed for a wide range of applications. For instance, many video games use synthetic three-dimensional scenes for gameplay, and virtual reality experiences allow for immersive experiences where users can interact with objects in a synthetic three-dimensional scene. In addition, synthetic three-dimensional scenes can be used to represent real-world scenes, e.g., by performing measurements of real-world scenes and reconstructing synthetic representations of the real-world scenes from the measurements.

Energy propagation between any two locations in a scene can vary greatly depending on geometric features within the scene. Since energy propagation varies spatially within the scene, it is important to accurately model energy propagation for applications such as rendering of sound or indirect lighting. However, in many cases, there is no readily-available source of data indicating how energy propagation varies spatially within a scene.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

The description generally relates to distance-based identification of geometric features. One example includes a computer-implemented method that can include accessing geometry data identifying locations of geometry in a three-dimensional synthetic scene. The method can also include generating a first distance field from the geometry data, the first distance field identifying respective distances from points in space in the three-dimensional synthetic scene to the nearest geometry in the three-dimensional synthetic scene. The method can also include performing volumetric curvature analysis on the first distance field to identify respective locations of geometric features in the three-dimensional synthetic scene. The method can also include based at least on the respective locations of the geometric features, estimating energy propagation variation values at the points in space in the three-dimensional synthetic scene. The method can also include generating an energy propagation variation field having the estimated energy propagation variation values. The method can also include outputting the energy propagation variation field.

Another example includes a system that includes a processor and storage storing computer-readable instructions. When executed by the processor, the computer-readable instructions cause the system to access geometry data identifying locations of geometry in a three-dimensional synthetic scene. When executed by the processor, the computer-readable instructions can also cause the system to perform volumetric curvature analysis of the geometry data to identify respective locations of geometric features in the three-dimensional synthetic scene. When executed by the processor, the computer-readable instructions can also cause the system to, based at least on the respective locations of the geometric features, estimate energy propagation variation values at points in space in the three-dimensional synthetic scene. When executed by the processor, the computer-readable instructions can also cause the system to output the estimated energy propagation variation values.

Another example includes a computer-readable medium storing executable instructions which, when executed by a processor, cause the processor to perform acts. The acts can include accessing geometry data identifying locations of geometry in a three-dimensional synthetic scene. The acts can also include generating a first distance field from the geometry data, the first distance field identifying respective distances from points in space in the three-dimensional synthetic scene to the nearest geometry in the three-dimensional synthetic scene. The acts can also include performing volumetric curvature analysis on the first distance field to identify respective locations of geometric features in the three-dimensional synthetic scene. The acts can also include based at least on the respective locations of the geometric features, estimating energy propagation variation values at the points in space in the three-dimensional synthetic scene. The acts can also include generating an energy propagation variation field having the estimated energy propagation variation values. The acts can also include outputting the energy propagation variation field.

The above-listed examples are intended to provide a quick reference to aid the reader and are not intended to define the scope of the concepts described herein.

### BRIEF DESCRIPTION OF THE DRAWINGS

The accompanying drawings illustrate implementations of the concepts conveyed in the present document. Features of the illustrated implementations can be more readily understood by reference to the following description taken in conjunction with the accompanying drawings. Like reference numbers in the various drawings are used wherever feasible to indicate like elements. In some cases, parentheticals are utilized after a reference number to distinguish like elements. Use of the reference number without the associated parenthetical is generic to the element. Further, the left-most numeral of each reference number conveys the FIG. and associated discussion where the reference number is first introduced.

FIGS. 1A, 1B, and 1C illustrate examples relating to energy propagation near an inside corner, consistent with some implementations of the present concepts.

FIGS. 2A, 2B, and 2C illustrate examples relating to energy propagation near a portal, consistent with some implementations of the present concepts.

FIGS. 3A, 3B, and 3C illustrate examples relating to energy propagation near an outside corner, consistent with some implementations of the present concepts.

FIG. 4 illustrates an example of a structure in a space, consistent with some implementations of the present concepts.

FIG. 5 illustrates an example of a binary field indicating the presence of geometry, consistent with some implementations of the present concepts.

FIG. 6 illustrates an example of a field that conveys distance to nearest geometry, consistent with some implementations of the present concepts.

FIGS. 7A and 7B illustrate outside corner detection, consistent with some implementations of the present concepts.

FIGS. 8A, 8B, 8C, 8D, 8E and 8F illustrate portal detection, consistent with some implementations of the present concepts.

FIG. 9 illustrates an example of a field that conveys distance to identified geometric features, consistent with some implementations of the present concepts.

FIG. 10 illustrates an example system, consistent with some implementations of the present concepts.

FIG. 11 is a flowchart of an example method in accordance with some implementations of the present concepts.

### DETAILED DESCRIPTION

### Overview

As noted above, a wide range of applications depend on having accurate data that conveys how energy propagation varies spatially within a scene. However, it is not always feasible to comprehensively simulate energy propagation within a scene, because this can be computationally intensive and utilize massive amounts of memory and/or storage resources. Furthermore, some applications are latency-sensitive and there are scenarios where it can be useful to quickly estimate energy propagation characteristics at runtime.

The disclosed implementations can overcome these deficiencies of conventional full-scale simulation approaches by utilizing volumetric curvature analysis to identify geometric features in a three-dimensional synthetic scene. As discussed more below, certain types of geometric features, such as outside corners and portals (e.g., doors, windows, etc.), tend to exert significant influence on the variation of energy propagation within a given scene. As a consequence, by identifying the location of such geometric features within a given scene, energy propagation variation can be reliably estimated without necessarily performing full-scale numerical wave simulations.

### Terminology

As used herein, the term “geometry” can refer to an arrangement of structures (e.g., physical objects) and/or open spaces in a scene. The term “scene” is used herein to refer to any physical, augmented, or virtual environment, and a “synthetic” scene is a digital representation of a scene. For instance, a synthetic representation of a physical scene (e.g., an auditorium, a sports stadium, a concert hall, etc.) can be obtained by measuring structures in the scene and reconstructing a digital representation of the physical scene from the measurements.

The geometry within a scene can be any structure that affects the propagation of energy within the scene. For instance, walls can cause occlusion, reflection, diffraction, and/or scattering of sound, etc. Some additional examples of structures that can affect energy propagation are furniture, floors, ceilings, vegetation, rocks, hills, ground, tunnels, fences, crowds, buildings, animals, stairs, etc.

### Sound Travel Examples

The following discussion uses some examples of sound propagation to motivate the disclosed adaptive sampling techniques. For a given wave pulse introduced by a sound source into a scene, the pressure response or “impulse response” at a listener arrives as a series of peaks, each of which represents a different path that the sound takes from the source to the listener. Listeners tend to perceive the direction of the first-arriving peak in the impulse response as the arrival direction of the sound, even when nearly-simultaneous peaks arrive shortly thereafter from different directions. This is known as the “precedence effect.” After the initial sound, subsequent reflections are received that generally take longer paths through the scene and become attenuated over time.

The initial first-arriving peak takes the shortest path through the air from a sound source to a listener in a given scene. In other words, the length of the initial sound path between any two points corresponds to the geodesic distance between those two points. The following examples illustrate how the rate at which energy propagation (such as initial sound) changes when propagating through a given scene can vary a function of location within the scene.

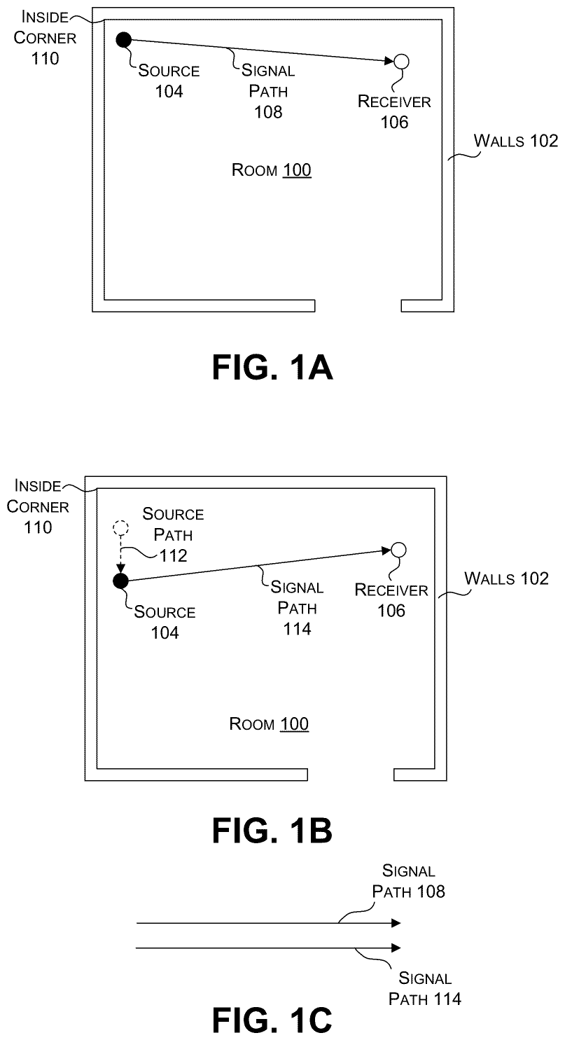

FIG. 1A shows a room 100 with walls 102. A source 104 emits a signal, such as a sound, to a receiver 106 along a signal path 108. Note source is near inside corner 110. FIG. 1B shows source 104 moving along a source path 112. A signal emitted by source 104 now follows signal path 114.

FIG. 1C shows a comparison of signal path 108 to signal path 112. Note that both signal paths have the same length. In other words, the movement of the source along source path 112 had no influence on the length of the signal path to receiver 106. More generally, movement of energy sources or energy receivers nearby inside corners tends to have very little effect on the path that energy takes when propagating from the source to the receiver.

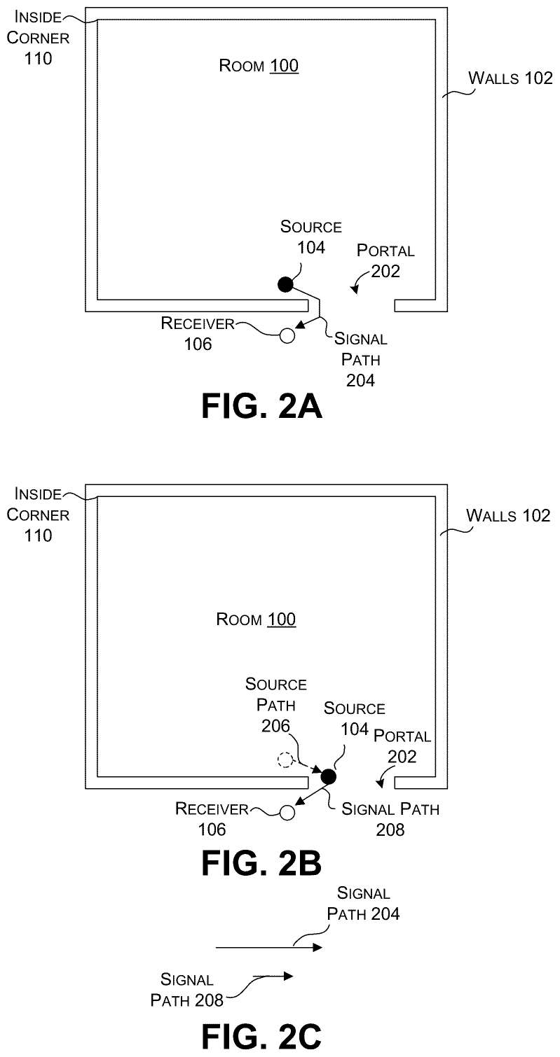

FIG. 2A shows a scenario where source 104 is located inside room 100 near a portal 202, and receiver 106 is located just outside the room near the portal. A signal from source 104 travels signal path 204 to arrive at the receiver. FIG. 2B shows source 104 moving along source path 206 to a new location. A signal emitted by the source now follows signal path 208.

FIG. 2C shows a comparison of signal path 204 to signal path 208. Note that signal path 204 is significantly longer than signal path 208. However, source path 206 is the same length as source path 112 shown in FIG. 1B. Thus, the movement of the source near portal 202 had a significant influence on the length of the signal path to the receiver, whereas the movement of the source near inside corner 110 had no influence on the length of the signal path. More generally, movement of energy sources or energy receivers near portals tends to have a significant effect on the path length that energy takes when propagating from the source to the receiver. In addition to the changes in path length illustrated in FIGS. 2A, 2B, and 2C, movement of an energy source or receiver near a portal also changes how diffracted energy is attenuated. For instance, diffraction attenuation of energy propagating through a portal changes significantly with movement around the edges or to the side of a portal relative to energy propagating straight through the portal.

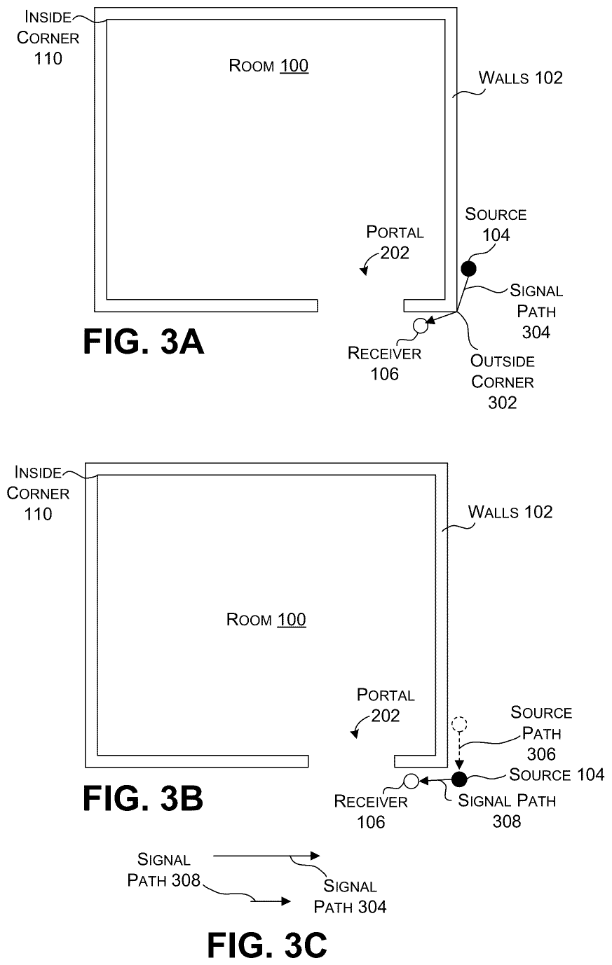

FIG. 3A shows a scenario where source 104 is located outside room 100 near outside corner 302, and receiver 106 is located just around the outside corner. A signal from source 104 travels signal path 304 to arrive at the receiver. FIG. 3B shows source 104 moving along source path 306 to a new location. A signal emitted by the source now follows signal path 308.

FIG. 3C shows a comparison of signal path 304 to signal path 308. Note that signal path 304 is significantly longer than signal path 308. However, source path 306 is the same length as source path 112 shown in FIG. 1B. Thus, the movement of the source near outside corner 302 had a significant influence on the length of the signal path to the receiver, whereas the movement of the source near inside corner 110 had no influence on the length of the signal path. More generally, movement of energy sources or energy receivers near outside corners tends to have a significant effect on the path length that energy takes when propagating from the source to the receiver. In addition to the changes in path length illustrated in FIGS. 3A, 3B, and 3C, movement of an energy source or receiver near an outside corner also changes how diffracted energy is attenuated, depending on the bend angle of the path of the energy at the occlusion point on the outside corner.

More generally, the examples above illustrate the point that energy propagation in a scene does not change uniformly as the source and receiver move relative to one another in the scene. Movement of a source or receiver near structures such as an inside corner can have very little influence on the length of a signal path and/or diffraction attenuation between the source and receiver. On the other hand, movement of the source or receiver near a portal or outside corner can have a very significant effect on the length of a signal path between the source and receiver and/or on diffraction attenuation of energy propagating from the source to the receiver.

### Example Scene

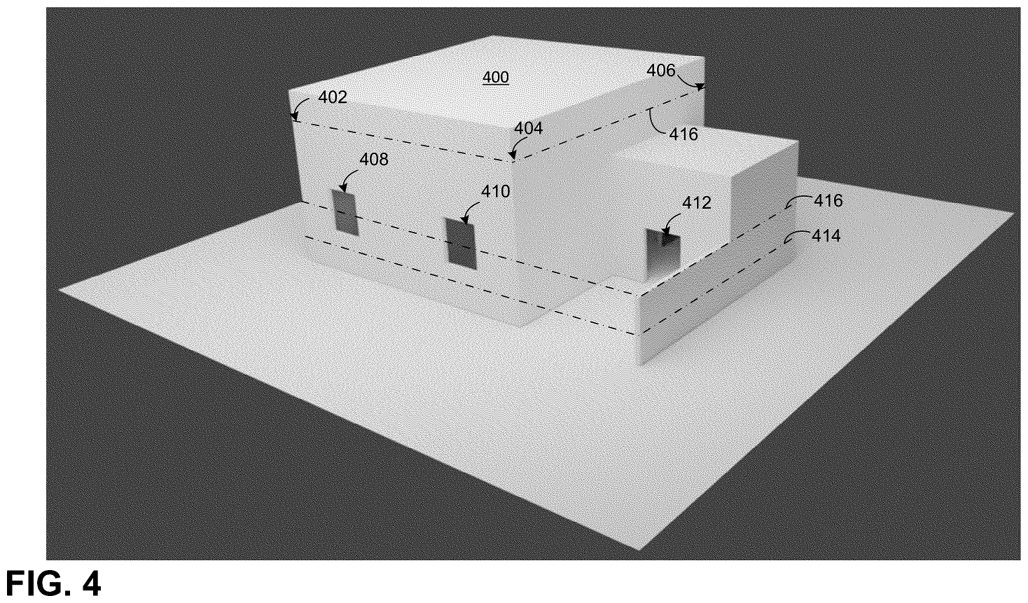

FIG. 4 illustrates a three-dimensional synthetic scene with a building 400. Outside corners 402, 404, and 406 and portals 408, 410, and 412 are visible in FIG. 4. Also shown are three planes, lower plane 414, middle plane 416, and upper plane 418. These planes are referenced in the examples below to convey how the disclosed techniques can be employed to identify geometric features such as the outside corners and portals by volumetric curvature analysis.

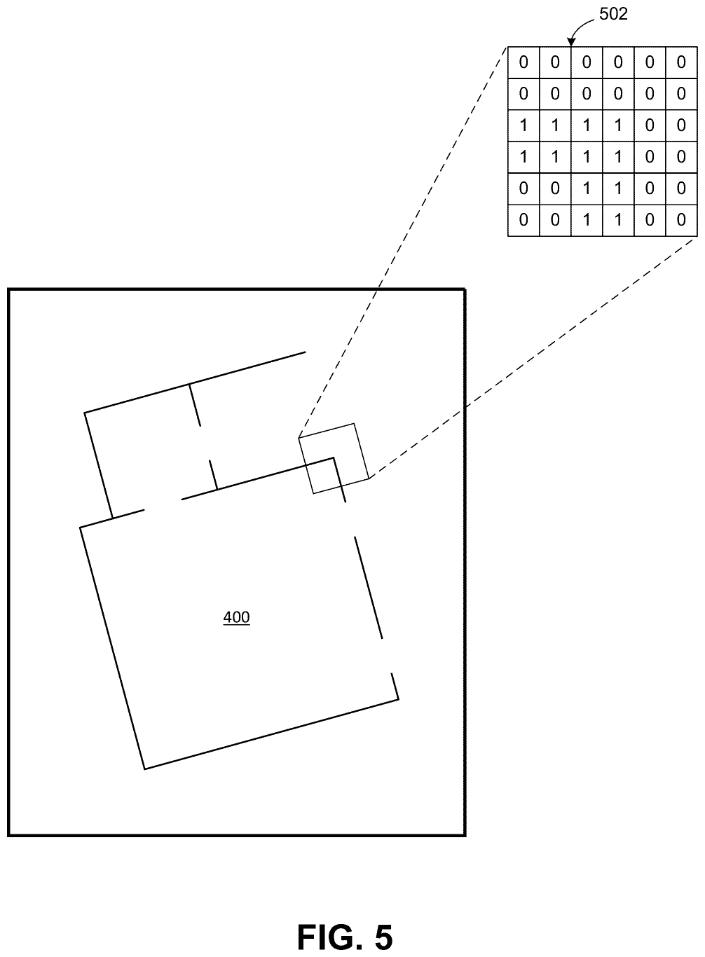

FIG. 5 shows an overhead view of a “slice” of the scene with building 400 taken along middle plane 416, which intersects all of the portals and outside corners of the building. A geometry presence field 502 uses binary values of 1 to convey the presence of geometry at each point (e.g., a voxel) in the middle plane, as can be seen representing the walls forming an outside corner. Note that FIG. 5 only shows a portion of the geometry presence field and that in practice the field can encompass the entire plane. In addition, similar fields can be provided for each horizontal slice of the scene, where the stacked fields collectively convey whether or not geometry is present within any given voxel.

### Volumetric Curvature Analysis Algorithm

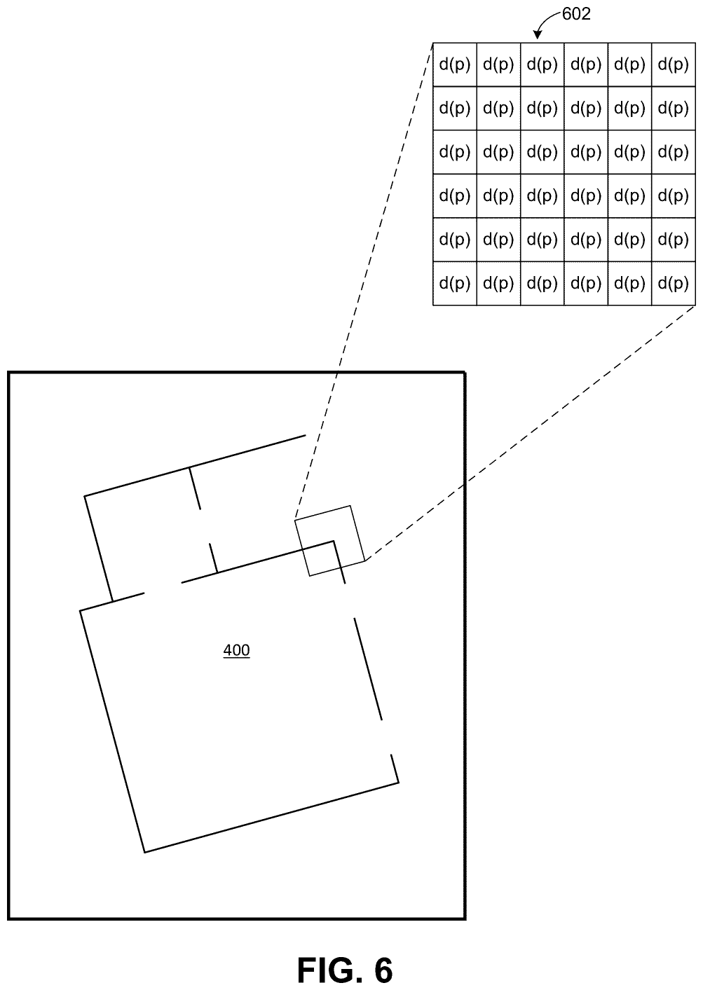

Given a three-dimensional representation of the presence or absence of geometry at each voxel within a scene, the following describes how specific geometric features can be identified using volumetric curvature analysis. Generally, the algorithm can proceed by computing, for each voxel in the scene, the distance to the nearest geometry. For example, FIG. 6 shows a three-dimensional distance field 602 with values d(p) for each grid cell, e.g., voxel or other grid representation of the scene. Next, the distance field can be analyzed to automatically detect features like corners and portals, where energy propagation pathways change significantly in strength or direction.

More specifically, the algorithm includes the following steps:
(1) Compute the closest distance to geometry, e.g., using Fast Marching Method (FMM), which is one way to solving the Eikonal partial differential equation.
(2) At every point not inside geometry, compute the Hessian (a square matrix of second ordered partial derivatives of the distance) and then diagonalize the resulting matrix.
(3) Run detectors on the three principal curvatures, in some cases employing inhibition or culling based on original distance, distance gradient, and/or curvature directions.
(4) A threshold can be applied to results computed using the detectors to obtain a list of detected geometric features, also referred to as “emitter” points below.
(5) The distance from each point in the scene to the emitters can be employed as an estimate of variation, e.g., by generating a three-dimensional field populated with values proportional to the distance from the emitters of each point in the scene.

At point p∈ [symbol] ³, let the computed distance field to the closest geometry be denoted d(p), in units of grid cells. Then in the neighborhood of the point p for a small vector displacement Δp, consider the following Taylor series approximation:

$$d ( p + Δ p ) \approx d ( p ) + ∇ d ( p ) \cdot Δ p + \frac{1}{2} Δ {p}^{T} H ( p ) Δ p$$

where ∇d(p) is the distance field's gradient and H(p) its Hessian:

$$H ( p ) ≡ [ \begin{matrix}\frac{{\partial }^{2} d}{\partial {x}^{2}} ( p ) & \frac{{\partial }^{2} d}{\partial x \partial y} ( p ) & \frac{{\partial }^{2} d}{\partial x \partial z} ( p ) \\ \frac{{\partial }^{2} d}{\partial x \partial y} ( p ) & \frac{{\partial }^{2} d}{\partial {y}^{2}} ( p ) & \frac{{\partial }^{2} d}{\partial y \partial z} ( p ) \\ \frac{{\partial }^{2} d}{\partial x \partial z} ( p ) & \frac{{\partial }^{2} d}{\partial y \partial z} ( p ) & \frac{{\partial }^{2} d}{\partial {z}^{2}} ( p )\end{matrix} ]$$

at p. The approximation sums constant, linear, and quadratic terms where the third term contains the curvature information for distance evaluated over a straight line starting at p in any 3D direction Δp. The Hessian of the discretized distance function can be evaluated numerically using second-order central differences.

H(p) is a symmetric 3×3 matrix, and thus the eigenvalues are real-valued. To analyze curvature, let [symbol] {λ [symbol] ₀(p), λ₁(p), λ₂(p)} be the eigenvalues H(p) indexed in increasing order, and [symbol] {V [symbol] ₀(p), V₁(p), V₂(p)} be the corresponding unit-length eigenvectors. In other words, H Vᵢ=λᵢ Vᵢ for i∈{0,1,2} and ∥Vᵢ∥=1. The eigenvectors form an orthogonal basis: Vᵢ·Vⱼ=δᵢⱼ. The full diagonalization (eigen-decomposition) may be expressed as:

$$H = {[ \begin{matrix}{V}_{0} & {V}_{1} & {V}_{2}\end{matrix} ]}^{T} [ \begin{matrix}{λ}_{0} & 0 & 0 \\ 0 & {λ}_{1} & 0 \\ 0 & 0 & {λ}_{2}\end{matrix} ] [ \begin{matrix}{V}_{0} & {V}_{1} & {V}_{2}\end{matrix} ]$$

$$where :$$

$$R ≡ [ \begin{matrix}{V}_{0} & {V}_{1} & {V}_{2}\end{matrix} ]$$

is the 3×3 rotation matrix of eigenvectors (forming its columns), and R⁻¹=R^{T}. The principal curvatures are related to the eigenvalues via:

$${κ}_{i} ≡ \frac{{λ}_{i}}{{( 1 + {( ∇ d \cdot {V}_{i} )}^{2} )}^{3 / 2}} .$$

Note that ∇d·Vᵢ in the denominator represents the first derivative of distance in the direction Vᵢ. The Vᵢ are referred to herein as the principal curvature directions. Computation and then diagonalization of the Hessian of a scalar 3D function can be employed to implement volumetric curvature analysis of the scene as follows. Note that the detectors described below employ the eigenvalues directly for volumetric curvature analysis rather than the principal curvatures.

The Laplacian at p denoted:

$$ℒ ( p ) ≡ \frac{{\partial }^{2} d}{\partial {x}^{2}} ( p ) + \frac{{\partial }^{2} d}{\partial {y}^{2}} ( p ) + \frac{{\partial }^{2} d}{\partial {z}^{2}} ( p ) = Tr ( H ( p ) ) = {λ}_{0} ( p ) + {λ}_{1} ( p ) + {λ}_{2} ( p )$$

represents a measure of overall curvature. Its sign represents convexity: positive near convex (outside) corners of the geometry, and negative on inside corners and points near the geometry's medial axis where more than one occupied point is closest to p. One way to implement volumetric curvature analysis is to employ the sign and magnitude of the Laplacian as a type of feature detector. However, by analyzing the three principal curvatures individually rather than just the sum, geometric features such as outside corners and portals can be more accurately detected.

Corner Detector: Let [symbol] be a point nearing an outside corner. An unsigned detector is given by:

$${𝒞}^{+} ( p ) ≡ {λ}_{2} ( p ) .$$

A signed version can be made via

$$𝒞 ( p ) ≡ \{ \begin{matrix}{λ}_{0} ( p ) , & ℒ ( p ) < 0 \\ {λ}_{2} ( p ) & ℒ ( p ) \geq 0\end{matrix}$$

More positive values represent more convexity. On the other hand, inside corners, and in general points on the geometry's medial axis, are highly negative. Using the signed detector stops detection of anomalous corners along straight walls not aligned with the coordinate axes of the voxelization: tiny convexities and concavities tend to alternate along such an edge and thus cancel each other out after smoothing, which is discussed more below. The corresponding eigenvector represents the direction of largest curvature going around the corner, denoted:

$${V}_{{𝒞}^{+}} ( p ) ≡ {V}_{2} ( p )$$

$$and :$$

$${V}_{𝒞} ( p ) ≡ \{ \begin{matrix}{V}_{0} ( p ) , & ℒ ( p ) < 0 \\ {V}_{2} ( p ) , & ℒ ( p ) \geq 0\end{matrix} .$$

V [symbol] (p)×∇d(p) represents the direction along the edge itself.

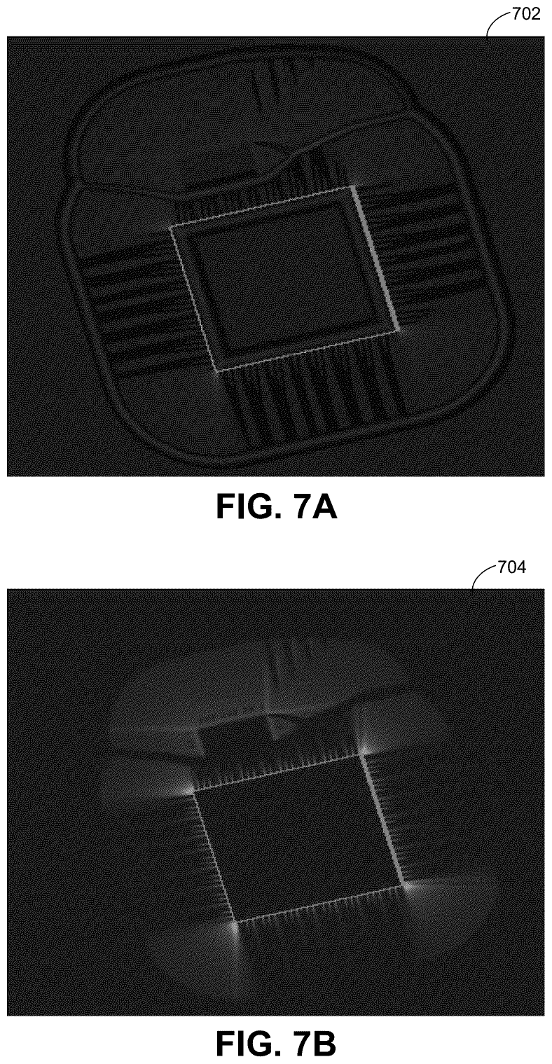

FIG. 7A shows an outside corner detector field 702 populated with values of the signed detector [symbol] (p) through the upper plane 418. Darker areas represent negative values and lighter areas represent positive values. As can be seen in FIG. 7A, the outside corners are relatively light in color compared to the rest of the scene. FIG. 7B shows a thresholded field 704, where the values from outside corner detector field 702 are processed using a threshold τ [symbol] ≡0.2. Additional details on thresholding are provided below. Note that the outside corners of building 400 are clearly distinguishable from the rest of thresholded field 704.

Portal Detector: Let [symbol] be a point nearing a pinched constriction, like a door or window. Portals can be detected as points that are saddles in distance: where distance reaches a local maximum in two principal directions (λ₀<0, λ₁<0) across the portal, and a local minimum in the remaining direction (λ₂>0) through the portal. One portal detector can be implemented using by the sum of these three components:

$$\tilde{𝒫} ( p ) ≡ - {λ}_{0} ( p ) - {λ}_{1} ( p ) + {λ}_{2} ( p ) .$$

Note the similarity with the Laplacian, except for the sign adjustments. The eigenvector corresponding to the largest eigenvalue represents the portal “through” direction:

$${V}_{𝒫} ( p ) ≡ {V}_{2} ( p ) .$$

Another example of a portal detector tests that the middle eigenvalue is negative, excluding an unwanted response near the portal edges:

$$𝒫 ( p ) ≡ \{ \begin{matrix}0 , & {λ}_{1} ( p ) \geq 0 \\ \tilde{𝒫} ( p ) , & {λ}_{1} ( p ) < 0\end{matrix} .$$

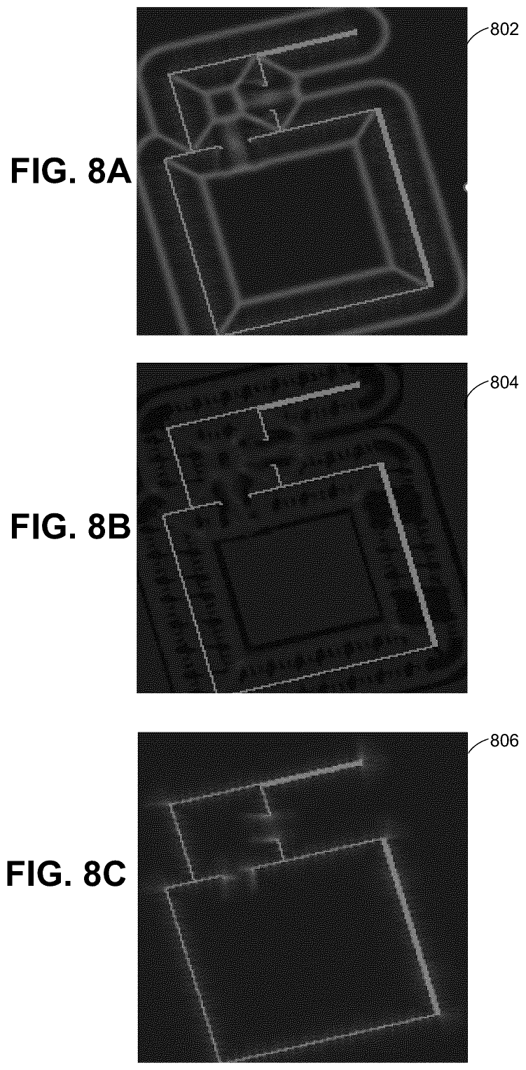

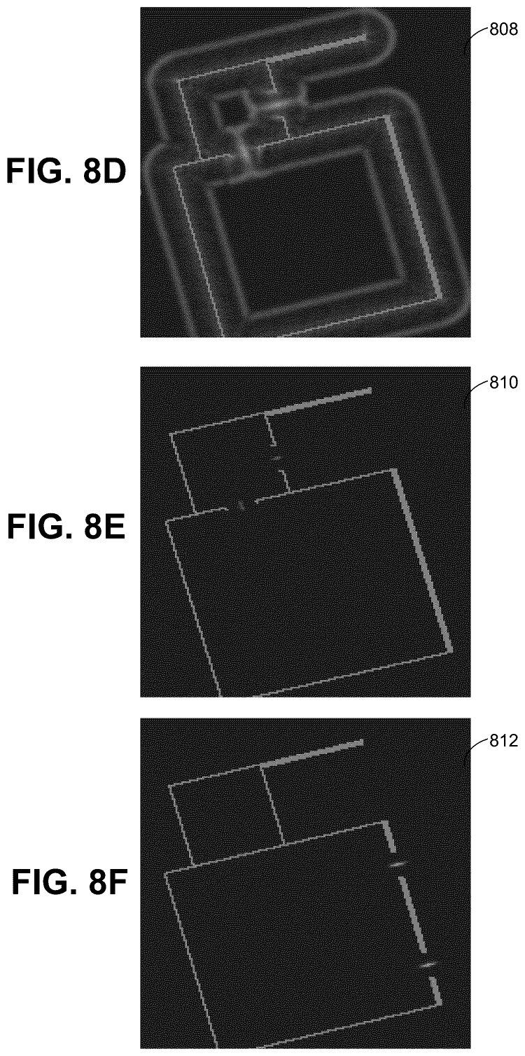

FIG. 8A shows a first portal detector component field 802 populated with values of λ₀(p) through the lower plane 414. FIG. 8B shows a second portal detector component field 804 populated with values of −λ₁(p) through the lower plane 414. FIG. 8C shows a third detector component field 806 populated with values of λ₂(p) through the lower plane 414.

FIG. 8D shows a portal detector component sum field 808 populated with values of [symbol] (p) through the lower plane 414. FIG. 8E shows a thresholded portal detector component sum field 810, where the portal detector components are processed using a threshold [symbol] ≡0.8. Additional details on thresholding are provided below. Note that the center of two portals intersected by lower plane 414 are visible in the thresholded portal detector component sum field 810. One of these portals, 412, is visible from the exterior view of building 400 shown in FIG. 4, the other portal is an interior portal not visible in FIG. 4.

FIG. 8F shows another thresholded portal detector component sum field 812 through middle plane 416. Note that different portals (408 and 410) are visible in the field. This is because the middle plane intersects the center of these portals, and the detector value peaks at these locations in three-dimensional space.

In some implementations, robustness of the above detectors can be improved by spatially smoothing using two passes of a filter, such as a triangle filter, in each of the XYZ dimensions. Note that the filter is not allowed to span geometric boundaries. This removes aliasing effects from voxelization in the immediate vicinity of the geometry.

The above detectors can also be augmented by detector inhibition, e.g., by setting their values to 0 using additional predicates based on distance magnitude, distance gradient direction, and/or feature direction. For instance, excluding points where d<0.8 (in units of grid cells) effectively removes concave (inside) corners in the immediate vicinity of geometry. Note that at a convex (outside corner) the distance of an adjacent free voxel must be d≥1; only a point immediately adjacent to an inside corner can have a smaller distance.

For observers limited to human height above ground, a detector can be set to zero when its corresponding feature direction is not mostly orthogonal to Z (the up direction) via:

$$‖ V \times Z ‖ < sin θ *$$

where V is the feature direction. For instance, a threshold angle of 60° can be employed. This discards corners resulting from variation in terrain height as well as wall tops and beams/lintels, leaving only floorplan type features. Similarly, this also discards trapdoors as portals, leaving windows and doors where the normal to the opening is in the XY plane. Some implementations can also exclude points where the distance gradient is not primarily orthogonal to the Z axis via:

$$\frac{‖ ∇ d \times Z ‖}{‖ ∇ d ‖} < sin θ * .$$

In some implementations, the distance field is specified in units of grid cells or voxels. In this case, the following thresholds can be employed for detecting corners and portals:

[symbol]

≡0.2,

[symbol]

≡0.8.

A corner “emitter” point can be established at p* if [symbol] (p*)> [symbol] and p* is immediately adjacent to geometry: d(p*)≤1. For portals, some implementations apply the test [symbol] (p*)> [symbol] and d(p*)> [symbol] ; that is, the portal point must be above threshold and not too near geometry.

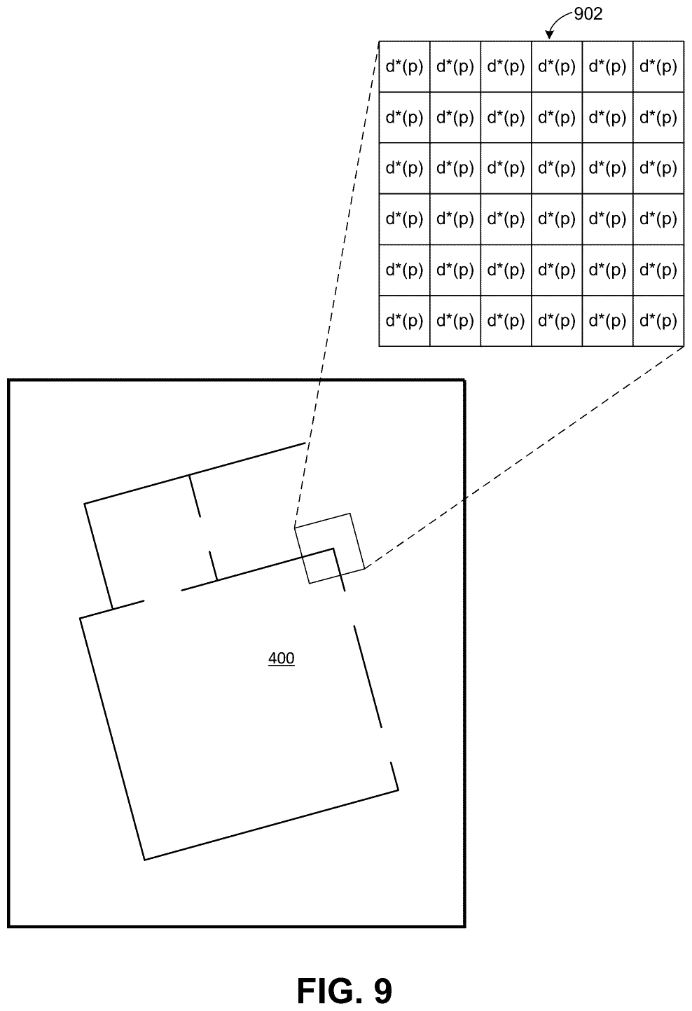

Once each of the geometric features is detected as described above as an “emitter” point, another distance field 902 can be computed, as shown in FIG. 9A. Here, d*(p) represents the distance from each point in the scene to the nearest emitter point and can be computed using Fast Marching Method. Note that this approach also respects the geometric boundaries, that is, the distance field flows around places where the space is occupied by geometry. The closer the distance to an emitter point, the more acoustic variation we expect. One estimate of energy propagation variation is given by:

$$ε ( p ) ≡ - log d * ( p ) .$$

which can be employed to populate an energy propagation variation field 904, as shown in FIG. 9B. Other estimates of variation based on the {p*} can be substituted, such as making each emitter superimpose or diffuse its contribution rather than finding the closest distance to any p*. A more direct relation between the detector fields and the final estimate avoiding thresholding is also possible.

### Example System

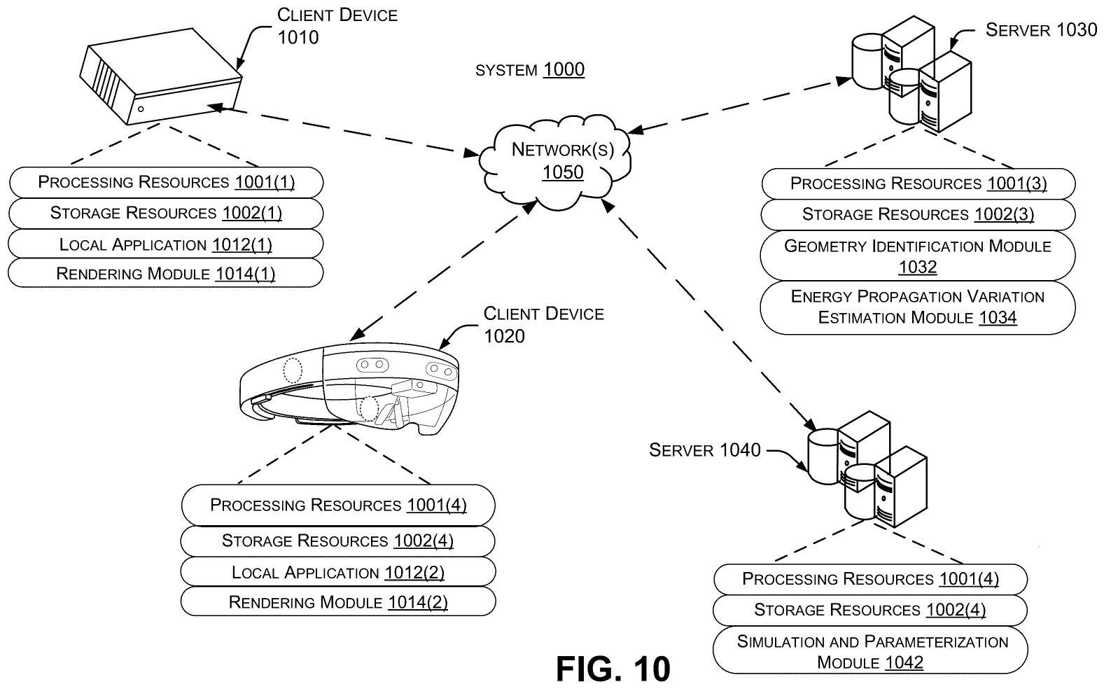

The present implementations can be performed in various scenarios on various devices. FIG. 10 shows an example system 1000 in which the present implementations can be employed, as discussed more below.

As shown in FIG. 10, system 1000 includes a client device 1010 (e.g., a video game console), a client device 1020 (e.g., a virtual or augmented reality headset), a server 1030, and a server 1040, connected by one or more network(s) 1050. Note that the client devices can also be embodied in other mobile device form factors such as laptops, tablets, or mobile phones, and/or as stationary devices such as desktops. Likewise, the servers can be implemented using various types of computing devices. In some cases, any of the devices shown in FIG. 10, but particularly the servers, can be implemented in data centers, server farms, etc.

Certain components of the devices shown in FIG. 10 may be referred to herein by parenthetical reference numbers. For the purposes of the following description, the parenthetical (1) indicates an occurrence of a given component on client device 1010, (2) indicates an occurrence of a given component on client device 1020, (3) indicates an occurrence on server 1030, and (4) indicates an occurrence on server 1040. Unless identifying a specific instance of a given component, this document will refer generally to the components without the parenthetical.

Generally, the devices 1010, 1020, 1030, and/or 1040 may have respective processing resources 1001 and storage resources 1002, which are discussed in more detail below. The devices may also have various modules that function using the processing and storage resources to perform the techniques discussed herein. The storage resources can include both persistent storage resources, such as magnetic or solid-state drives, and volatile storage, such as one or more random-access memory devices. In some cases, the modules are provided as executable instructions that are stored on persistent storage devices, loaded into the random-access memory devices, and read from the random-access memory by the processing resources for execution.

Client devices 1010 and 1020 can include a local application 1012, such as a video game or augmented/virtual reality game. The local application can invoke a rendering module 1014 to render audio and/or graphics at runtime. The local application can invoke a rendering module 1014 to render audio and/or graphics at runtime based on precomputed parameters received from server 1040, as described more below.

Server 1030 can include a geometry identification module 1032 that identifies geometric features such as outside corners and portals. Server 1030 can also include an energy propagation variation estimation module 1034. The energy propagation variation estimation module can employ the identified geometric features to generate fields reflecting how energy propagation varies as a function of location in space within scene(s) provided by the local application. In some implementations, the energy propagation values are obtained by identifying outside corners and portals, e.g., as identified by an application developer. Then, a negative log value of the distance of each point in a given scene from the nearest outside corner or portal can be used as an estimate of energy propagation variation at that point.

Server 1040 can include a simulation and parameterization module. The simulation and parameterization module can receive identified geometric features and/or energy propagation fields from server 1030 and simulate energy propagation in the scenes. Parameters representing characteristics of energy propagation can be derived from the simulations and provided with the scenes for use by the rendering module on the respective client devices.

### Example Method

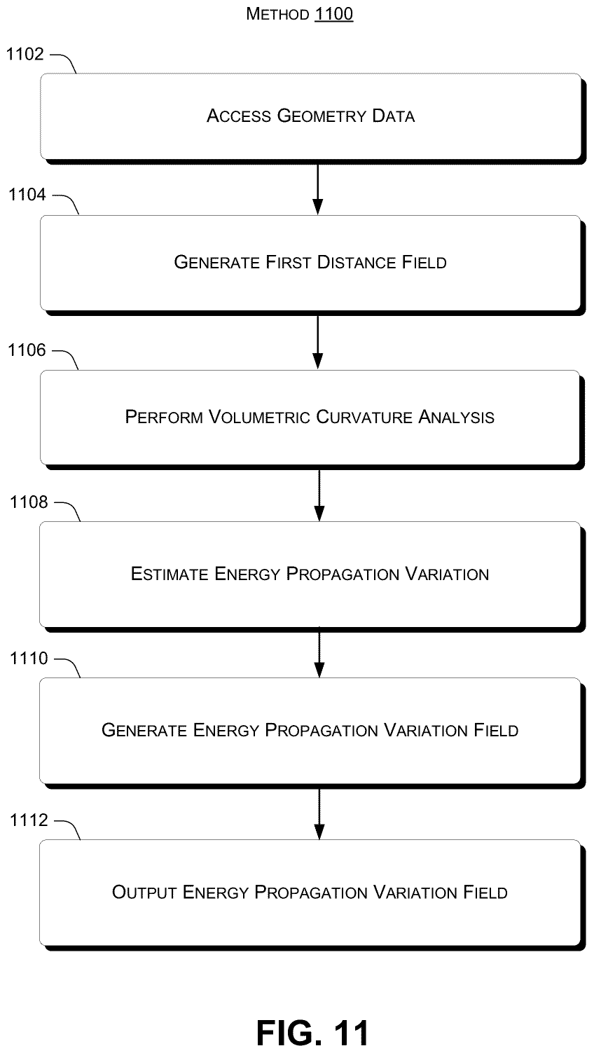

FIG. 11 shows a method 1100 that can be employed to estimate energy propagation variation in a synthetic three-dimensional scene. Method 1100 can be implemented on many different types of devices, e.g., by one or more cloud servers, by a client device such as a laptop, tablet, or smartphone, or by combinations of one or more servers, client devices, etc.

At block 1102, method 1100 can access geometry data identifying locations of geometry in a three-dimensional synthetic scene. For instance, in some implementations, the three-dimensional synthetic scene is represented as a voxel map, and the geometry data is provided as a three-dimensional field of Boolean values indicating whether a given voxel is occupied by geometry.

At block 1104, method 1100 can generate a first distance field from the geometry data. The first distance field can be a three-dimensional field that identifies respective distances from points in space in the three-dimensional synthetic scene to the nearest geometry in the three-dimensional synthetic scene. As noted previously, in some implementations, the first distance field is generated using Fast Marching Method.

At block 1106, method 1100 can perform volumetric curvature analysis on the first distance field to identify respective locations of geometric features in the three-dimensional synthetic scene. For instance, the geometric features can include outside corners or portals that are detected using eigenvalues of a Hessian calculated over the first distance field.

At block 1108, method 1100 can estimate energy propagation variation values at the points in space in the three-dimensional synthetic scene. As noted, the energy propagation variation can be estimated based at least on the respective locations of the geometric features. For instance, some implementations may apply a negative log function to a second distance field that identifies respective distances from the points in space to the geometric features. As another example, some implementations may model the geometric features as charged particles and use Poisson's equation to estimate the variation in energy propagation as a function of distance to the nearest geometric feature.

At block 1110, method 1100 can output the energy propagation variation field. For instance, as noted previously, the energy propagation variation field can be output for simulation of energy propagation using an adaptive sampling approach, where the adaptive sampling distributes simulation probes in the three-dimensional synthetic scene based on the energy propagation variation field. Simulations can be performed at the probed locations to derive parameters that indicate how energy travels to/from the probed locations in the synthetic three-dimensional synthetic scene. These parameters can be used for subsequent rendering of sound and/or graphics by an application.

### Example Parameterization and Rendering of Initial Sound

As noted above, one way to employ the disclosed techniques is to employ an energy propagation variation field to determine where sampling probes are deployed in a given scene. Simulations by each sampling probe can be implemented to determine fields of one or more acoustic parameters. For instance, a two-dimensional field can represent a horizontal “slice” within a given scene. Thus, different acoustic parameter fields can be generated for different vertical heights within a scene to create a volumetric representation of sound travel for the scene with respect to the listener location. Generally, the relative density of each encoded field can be a configurable parameter that varies based on various criteria such as the energy propagation variation at each point. Relatively dense fields can be used to obtain more accurate representations where energy propagation variation is high, and sparser fields can be employed to obtain computational efficiency and/or more compact representations where energy propagation is not as high.

For instance, probes can be located more densely near outside corners or portals, and located more sparsely in a wide-open space (e.g., outdoor field or meadow) or near inside corners. In addition, vertical dimensions of the probes can be constrained to account for the height of human listeners, e.g., the probes may be instantiated with vertical dimensions that roughly account for the average height of a human being.

In acoustic probing implementations, parameters can include initial sound parameters representing loudness of the initial sound path, the departure direction of the initial sound path from the source, and/or the arrival direction of the initial sound path at the listener. Chaitanya, et al., “Directional sources and listeners in interactive sound propagation using reciprocal wave field coding,” ACM Transactions on Graphics (TOG), 2020, 39(4), 44-1. Raghuvanshi, et al., “Parametric wave field coding for precomputed sound propagation,” ACM Transactions on Graphics (TOG), 2014, 33(4), 1-11. Raghuvanshi, et al., “Parametric directional coding for precomputed sound propagation,” ACM Transactions on Graphics (TOG), 2018, 37(4), 1-14. Raghuvanshi et al., “Bidirectional Propagation of Sound,” U.S. Patent Publication No. US20210266693 A1, published Aug. 26, 2021.

Sound can be subsequently rendered at runtime based on the stored parameters. In some implementations, a received sound signal can convey directional characteristics of a runtime sound source, e.g., via a source directivity function (SDF). In addition, listener data can convey a location of a runtime listener and an orientation of the listener. The listener data can also convey directional hearing characteristics of the listener, e.g., in the form of a head-related transfer function (HRTF).

Initial sound can be rendered by modifying the input sound signal to account for both runtime source and runtime listener location and orientation. For instance, given the runtime source and listener locations, the rendering can involve identifying and interpolating the following encoded parameters that were precomputed using probes that are near the runtime listener location—initial delay time, initial loudness, departure direction, and arrival direction. The directivity characteristics of the sound source (e.g., the SDF) can encode frequency-dependent, directionally-varying characteristics of sound radiation patterns from the source. Similarly, the directional hearing characteristics of the listener (e.g., HRTF) encode frequency-dependent, directionally-varying sound characteristics of sound reception patterns at the listener.

The sound source data for the input event can include an input signal, e.g., a time-domain representation of a sound such as series of samples of signal amplitude (e.g., 44100 samples per second). The input signal can have multiple frequency components and corresponding magnitudes and phases. In some implementations, the input time-domain signal is processed using an equalizer filter bank into different octave bands (e.g., nine bands) to obtain an equalized input signal.

Next, a lookup into the SDF can be performed by taking the encoded departure direction and rotating it into the local coordinate frame of the input source. This yields a runtime-adjusted sound departure direction that can be used to look up a corresponding set of octave-band loudness values (e.g., nine loudness values) in the SDF. Those loudness values can be applied to the corresponding octave bands in the equalized input signal, yielding nine separate distinct signals that can then be recombined into a single SDF-adjusted time-domain signal representing the initial sound emitted from the runtime source. Then, the encoded initial loudness value can be added to the SDF-adjusted time-domain signal.

The resulting loudness-adjusted time-domain signal can be input to a spatialization process to generate a binaural output signal that represents what the listener will hear in each ear. For instance, the spatialization process can utilize the HRTF to account for the relative difference between the encoded arrival direction and the runtime listener orientation. This can be accomplished by rotating the encoded arrival direction into the coordinate frame of the runtime listener's orientation and using the resulting angle to do an HRTF lookup. The loudness-adjusted time-domain signal can be convolved with the result of the HRTF lookup to obtain the binaural output signal. For instance, the HRTF lookup can include two different time-domain signals, one for each ear, each of which can be convolved with the loudness-adjusted time-domain signal to obtain an output for each ear. The encoded delay time can be used to determine the time when the listener receives the individual signals of the binaural output.

Using the approach discussed above, the SDF and source orientation can be used to determine the amount of energy emitted by the runtime source for the initial path. For instance, for a source with an SDF that emits relatively concentrated sound energy, the initial path might be louder relative to the reflections than for a source with a more diffuse SDF. The HRTF and listener orientation can be used to determine how the listener perceives the arriving sound energy, e.g., the balance of the initial sound perceived for each ear.

### Further Implementations

As noted above, one way to employ the disclosed techniques involves using the estimated energy propagation variation to determine where sampling probes are deployed in a three-dimensional synthetic scene. The sampling probes can be employed to perform simulations of energy propagation to or from the probed locations, and the parameters such as loudness or direction can be computed at simulation time. Later, at runtime, the parameters can be employed to render an energy signal.

In other implementations, the disclosed techniques can be performed for runtime identification of geometric features and/or estimation of energy propagation variation. For example, consider a video game where a user moves within a scene and occasionally discovers a new area. If the new area is not overly large or complex, the disclosed techniques can be employed at runtime of the video game. In some cases, e.g., where energy travels near a single portal or outside corner, energy signals can be rendered using precomputed parameters for those scenarios. For instance, a single set of precomputed parameters for areas near outside corners can be stored and employed at runtime and used to render energy signals near any newly-detected outside corner. Similar techniques can be employed for portals.

In addition, some implementations may employ trained classifiers, such as neural networks, support vector machines, or decision trees to identify geometric features. Given sufficient training data, e.g., examples of scenes with labeled geometric features, it is plausible to use features such as a Laplacian, Hessian, and/or eigenvalues of a Hessian to train a machine learning model to recognize geometric features. In addition, some implementations may use learnable thresholds for geometric feature detection, e.g., values for [symbol] and [symbol] can be learned over time using feedback.

### Technical Effect

As noted above, one way to model energy propagation variation in a three-dimensional synthetic scene involves performing a full-scale wave simulation of every location in the scene. However, this approach is not practical for large scenes that are represented at relatively fine levels of granularity. The disclosed techniques can estimate energy propagation variation as a function of distance to detected geometric features. This can be performed much more quickly, and using far fewer computing and memory resources, than full-scale simulations. In addition, because of the relatively compact memory requirements and fast computation of the disclosed techniques, runtime detection of geometric features and estimation of energy propagation variation is feasible.

### Device Implementations

As noted above with respect to FIG. 10, system 1000 includes several devices, including a client device 1010, a client device 1020, a server 1030, and a server 1040. As also noted, not all device implementations can be illustrated, and other device implementations should be apparent to the skilled artisan from the description above and below.

The term “device”, “computer,” “computing device,” “client device,” and or “server device” as used herein can mean any type of device that has some amount of hardware processing capability and/or hardware storage/memory capability. Processing capability can be provided by one or more hardware processors (e.g., hardware processing units/cores) that can execute data in the form of computer-readable instructions to provide functionality. Computer-readable instructions and/or data can be stored on storage, such as storage/memory and or the datastore. The term “system” as used herein can refer to a single device, multiple devices, etc.

Storage resources can be internal or external to the respective devices with which they are associated. The storage resources can include any one or more of volatile or non-volatile memory, hard drives, flash storage devices, and/or optical storage devices (e.g., CDs, DVDs, etc.), among others. As used herein, the term “computer-readable media” can include signals. In contrast, the term “computer-readable storage media” excludes signals. Computer-readable storage media includes “computer-readable storage devices.” Examples of computer-readable storage devices include volatile storage media, such as RAM, and non-volatile storage media, such as hard drives, optical discs, and flash memory, among others.

In some cases, the devices are configured with a general-purpose hardware processor and storage resources. Processors and storage can be implemented as separate components or integrated together as in computational RAM. In other cases, a device can include a system on a chip (SOC) type design. In SOC design implementations, functionality provided by the device can be integrated on a single SOC or multiple coupled SOCs. One or more associated processors can be configured to coordinate with shared resources, such as memory, storage, etc., and/or one or more dedicated resources, such as hardware blocks configured to perform certain specific functionality. Thus, the term “processor,” “hardware processor” or “hardware processing unit” as used herein can also refer to central processing units (CPUs), graphical processing units (GPUs), controllers, microcontrollers, processor cores, or other types of processing devices suitable for implementation both in conventional computing architectures as well as SOC designs.

Alternatively, or in addition, the functionality described herein can be performed, at least in part, by one or more hardware logic components. For example, and without limitation, illustrative types of hardware logic components that can be used include Field-programmable Gate Arrays (FPGAs), Application-specific Integrated Circuits (ASICs), Application-specific Standard Products (ASSPs), System-on-a-chip systems (SOCs), Complex Programmable Logic Devices (CPLDs), etc.

In some configurations, any of the modules/code discussed herein can be implemented in software, hardware, and/or firmware. In any case, the modules/code can be provided during manufacture of the device or by an intermediary that prepares the device for sale to the end user. In other instances, the end user may install these modules/code later, such as by downloading executable code and installing the executable code on the corresponding device.

Also note that devices generally can have input and/or output functionality. For example, computing devices can have various input mechanisms such as keyboards, mice, touchpads, voice recognition, gesture recognition (e.g., using depth cameras such as stereoscopic or time-of-flight camera systems, infrared camera systems, RGB camera systems or using accelerometers/gyroscopes, facial recognition, etc.). Devices can also have various output mechanisms such as printers, monitors, etc.

Also note that the devices described herein can function in a stand-alone or cooperative manner to implement the described techniques. For example, the methods and functionality described herein can be performed on a single computing device and/or distributed across multiple computing devices that communicate over network(s) 1050. Without limitation, network(s) 1050 can include one or more local area networks (LANs), wide area networks (WANs), the Internet, and the like.

### Additional Examples

Various examples are described above. Additional examples are described below. One example includes a computer-implemented method comprising accessing geometry data identifying locations of geometry in a three-dimensional synthetic scene, generating a first distance field from the geometry data, the first distance field identifying respective distances from points in space in the three-dimensional synthetic scene to the nearest geometry in the three-dimensional synthetic scene, performing volumetric curvature analysis on the first distance field to identify respective locations of geometric features in the three-dimensional synthetic scene, based at least on the respective locations of the geometric features, estimating energy propagation variation values at the points in space in the three-dimensional synthetic scene, generating an energy propagation variation field having the estimated energy propagation variation values, and outputting the energy propagation variation field.

Another example can include any of the above and/or below examples where the geometric features include portals and outside corners.

Another example can include any of the above and/or below examples where the method further comprises generating a second distance field identifying respective distances from the points in space to the geometric features.

Another example can include any of the above and/or below examples where the method further comprises calculating the energy propagation variation field based on the second distance field.

Another example can include any of the above and/or below examples where the energy propagation variation field is populated with a negative log function of the second distance field.

Another example can include any of the above and/or below examples where the identifying the geometric features comprises computing a Hessian over the first distance field.

Another example can include any of the above and/or below examples where the identifying the geometric features comprises evaluating eigenvalues of the Hessian.

Another example can include any of the above and/or below examples where identifying the geometric features comprises sorting the eigenvalues in increasing order from a lowest eigenvalue to a middle eigenvalue to a highest eigenvalue.

Another example can include any of the above and/or below examples where identifying the outside corners comprises comparing the highest eigenvalue to a threshold.

Another example can include any of the above and/or below examples where identifying the portals comprises identifying local minimums using the eigenvalues.

Another example can include any of the above and/or below examples where the identifying the portals comprises calculating a sum of a negative of the lowest eigenvalue, a negative of the middle eigenvalue, and the highest eigenvalue.

Another example can include any of the above and/or below examples where identifying the portals comprises comparing the sum to a threshold.

Another example can include any of the above and/or below examples where the volumetric curvature analysis comprises spatial smoothing over detector component values computed from the eigenvalues.

Another example can include any of the above and/or below examples where the volumetric curvature analysis comprises setting detector component values computed from the eigenvalues to zero when one or more predicates are satisfied.

Another example can include any of the above and/or below examples where the one or more predicates relate to distance magnitude, distance gradient direction, or feature direction.

Another example includes a system comprising a processor and storage storing computer-readable instructions which, when executed by the processor, cause the system to access geometry data identifying locations of geometry in a three-dimensional synthetic scene, perform volumetric curvature analysis of the geometry data to identify respective locations of geometric features in the three-dimensional synthetic scene, based at least on the respective locations of the geometric features, estimate energy propagation variation values at points in space in the three-dimensional synthetic scene, and output the estimated energy propagation variation values.

Another example can include any of the above and/or below examples where the volumetric curvature analysis is based at least on respective distances of the points in space to nearest geometry.

Another example can include any of the above and/or below examples where the estimated energy propagation variation values are based on proximity of the points in space to the geometric features

Another example can include any of the above and/or below examples where the geometric features comprise at least one of outside corners or portals

Another example includes a computer-readable medium storing executable instructions which, when executed by a processor, cause the processor to perform acts comprising accessing geometry data identifying locations of geometry in a three-dimensional synthetic scene, generating a first distance field from the geometry data, the first distance field identifying respective distances from points in space in the three-dimensional synthetic scene to the nearest geometry in the three-dimensional synthetic scene, performing volumetric curvature analysis on the first distance field to identify respective locations of geometric features in the three-dimensional synthetic scene, and based at least on the respective locations of the geometric features, estimating energy propagation variation values at the points in space in the three-dimensional synthetic scene, generating an energy propagation variation field having the estimated energy propagation variation values, and outputting the energy propagation variation field.

### CONCLUSION

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims and other features and acts that would be recognized by one skilled in the art are intended to be within the scope of the claims.

1. A computer-implemented method comprising:
accessing geometry data identifying locations of geometry in a three-dimensional synthetic scene;
generating a first distance field from the geometry data, the first distance field identifying respective distances from points in space in the three-dimensional synthetic scene to the nearest geometry in the three-dimensional synthetic scene;
performing volumetric curvature analysis on the first distance field to identify respective locations of geometric features in the three-dimensional synthetic scene;
based at least on the respective locations of the geometric features, estimating energy propagation variation values at the points in space in the three-dimensional synthetic scene;
generating an energy propagation variation field having the estimated energy propagation variation values; and
outputting the energy propagation variation field.

2. The computer-implemented method of claim 1, the geometric features including portals and outside corners.

3. The computer-implemented method of claim 2, further comprising:
generating a second distance field identifying respective distances from the points in space to the geometric features.

4. The computer-implemented method of claim 3, further comprising:
calculating the energy propagation variation field based on the second distance field.

5. The computer-implemented method of claim 4, wherein the energy propagation variation field is populated with a negative log function of the second distance field.

6. The computer-implemented method of claim 2, wherein the identifying the geometric features comprises computing a Hessian over the first distance field.

7. The computer-implemented method of claim 6, wherein the identifying the geometric features comprises evaluating eigenvalues of the Hessian.

8. The computer-implemented method of claim 7, wherein identifying the geometric features comprises sorting the eigenvalues in increasing order from a lowest eigenvalue to a middle eigenvalue to a highest eigenvalue.

9. The computer-implemented method of claim 8, wherein identifying the outside corners comprises comparing the highest eigenvalue to a threshold.

10. The computer-implemented method of claim 8, wherein identifying the portals comprises identifying local minimums using the eigenvalues.

11. The computer-implemented method of claim 8, wherein the identifying the portals comprises calculating a sum of a negative of the lowest eigenvalue, a negative of the middle eigenvalue, and the highest eigenvalue.

12. The computer-implemented method of claim 11, wherein identifying the portals comprises comparing the sum to a threshold.

13. The computer-implemented method of claim 7, wherein the volumetric curvature analysis comprises spatial smoothing over detector component values computed from the eigenvalues.

14. The computer-implemented method of claim 7, wherein the volumetric curvature analysis comprises setting detector component values computed from the eigenvalues to zero when one or more predicates are satisfied.

15. The computer-implemented method of claim 14, the one or more predicates relating to distance magnitude, distance gradient direction, or feature direction.

16. A system, comprising:
a processor; and
storage storing computer-readable instructions which, when executed by the processor, cause the system to:
access geometry data identifying locations of geometry in a three-dimensional synthetic scene;
perform volumetric curvature analysis of the geometry data to identify respective locations of geometric features in the three-dimensional synthetic scene;
based at least on the respective locations of the geometric features, estimate energy propagation variation values at points in space in the three-dimensional synthetic scene; and
output the estimated energy propagation variation values.

17. The system of claim 16, the volumetric curvature analysis being based at least on respective distances of the points in space to nearest geometry.

18. The system of claim 17, the estimated energy propagation variation values being based on proximity of the points in space to the geometric features.

19. The system of claim 18, the geometric features comprising at least one of outside corners or portals.

20. A computer-readable medium storing executable instructions which, when executed by a processor, cause the processor to perform acts comprising:
accessing geometry data identifying locations of geometry in a three-dimensional synthetic scene;
generating a first distance field from the geometry data, the first distance field identifying respective distances from points in space in the three-dimensional synthetic scene to the nearest geometry in the three-dimensional synthetic scene;
performing volumetric curvature analysis on the first distance field to identify respective locations of geometric features in the three-dimensional synthetic scene; and
based at least on the respective locations of the geometric features, estimating energy propagation variation values at the points in space in the three-dimensional synthetic scene;
generating an energy propagation variation field having the estimated energy propagation variation values; and
outputting the energy propagation variation field.
